(19) United States
(12) Patent Application Publication
(10) Pub. No.: US 2008/0191729 A1
(43) Pub. Date: Aug. 14, 2008

(54) Thermal interface for electronic chip testing

(76) Inventors: Richard Lidio Blanco, Santa Clara, CA (US); Michael D. Hillman, Los Altos, CA (US)

Correspondence Address: PVF -- APPLE COMPUTER, INC.;c/o PARK, VAUGHAN & FLEMING LLP, 2820 FIFTH STREET, DAVIS, CA, 95618-7759, US

(21) Appl. No.: 11/704,768

(22) Filed: Feb. 9, 2007

(51) Int. Cl. H01L 21/66; G01R 31/26

(52) U.S. Cl. 324/765; 438/17; 257/E21.525

(57) ABSTRACT

An apparatus that performs electrical testing is described. This apparatus includes a first semiconductor die that is to be tested, and a connector configured to be coupled to a first surface of the first semiconductor die. Furthermore, a thermal interface in the apparatus is between a second surface of the first semiconductor die and a heat-removal device. This thermal interface includes a metal which is in a liquid state at an operating temperature of the semiconductor die during the testing.

### BACKGROUND

1. Field of the Invention

The present invention relates to heat-transfer techniques. More specifically, the present invention relates to test equipment that includes a low melting-point metal alloy which functions as a thermal interface during testing of electronic components.

2. Related Art

The functionality, performance, and operating speed of integrated circuits (ICs) have increased significantly in recent years. This has resulted in significantly increased power consumption and associated heat generation in these devices. Consequently, it is becoming a considerable challenge to manage this thermal load to maintain acceptable internal and external operating temperatures in these ICs. This problem is particularly acute during testing of bare semiconductor dies (at the wafer, die, or chip level) that are to be used in ICs, since these semiconductor dies are not yet packaged.

Proper thermal coupling to the semiconductor dies during testing is needed to accurately and precisely perform tests over a range of operating conditions (including specified limits of the semiconductor dies). To achieve these goals, the thermal interface material that is to be used between semiconductor dies and test equipment must meet several requirements. In particular, such a thermal interface material should have no impurities and should be removable to facilitate cleaning of the semiconductor dies after testing. Furthermore, the thermal interface material should conform to the surface of a semiconductor die at low pressures and should have a high bulk thermal conductivity. These properties ensure a low thermal impedance between the ATE and the semiconductor die. In addition, they reduce the probability of damaging the semiconductor die during testing; and reduce the complexity of the ATE.

Unfortunately, it is difficult meet all of these requirements using existing thermal interface materials. For example while existing thermally conductive materials (such as silicone-based grease or propylene glycol) have a moderate thermal conductivity, the thermal impedance associated with these thermal interface materials often limits the heat removal from the die. This has made it difficult to test semiconductor dies at maximum power or maximum operating temperatures, especially as the thermal load generated by successive generations of semiconductor dies has increased. Furthermore, silicone-based thermal greases often leave residue on the semiconductor die.

Hence what is needed are thermal interface materials that overcome the problems listed above.

### SUMMARY

One embodiment of the present invention provides an apparatus that performs electrical testing. This apparatus includes a first semiconductor die to be tested, and a connector configured to be coupled to a first surface of the first semiconductor die. Furthermore, a thermal interface in the apparatus is between a second surface of the first semiconductor die and a heat-removal device. This thermal interface includes a metal which is in a liquid state at an operating temperature of the semiconductor die during the testing.

In some embodiments, the apparatus includes a second semiconductor die that is to be simultaneously tested with the first semiconductor die. This second semiconductor die is adjacent to the first semiconductor die, a first surface of the second semiconductor die is coupled to the connector, and a second surface of the second semiconductor die is coupled to the thermal interface. Furthermore, in some embodiments the second surface of the second semiconductor die is in a different plane than the second surface of the first semiconductor die.

In some embodiments, the heat-removal device is coated with a layer that facilitates wetting with the thermal interface. For example, the layer may include a metal, such as gold, platinum, tantalum, titanium, tin, chromium, nickel, zinc, silver, and/or aluminum.

In some embodiments, the liquid metal is configured to wet to the second surface of the first semiconductor die. Furthermore, the liquid metal may include a metal alloy, such as gallium-indium-tin. In some embodiments, the liquid metal includes bismuth, lead, zinc, sliver, gold, tin, chromium, nickel, aluminum, palladium, platinum, tantalum, gallium, indium, and/or titanium. However, note that the liquid metal may include elements other than metals, such as diamond or graphite.

In some embodiments, the thermal interface includes a layer between the liquid metal and the heat-removal device and/or between the liquid metal and the first semiconductor die. Note that the layer has a bulk thermal conductivity which is greater than the bulk thermal conductivity of the liquid metal.

In some embodiments, the liquid metal has a melting temperature below room temperature.

In some embodiments, the thermal interface is removable and the liquid metal is configured to be cleaned off of the second surface of the first semiconductor die.

In some embodiments, electrical testing includes functional testing and/or burn-in testing.

Another embodiment provides a method for performing electrical testing. During this method, a thermal interface is applied to the second surface of the first semiconductor die to provide the thermal interface. Note that the thermal interface includes a metal which is in a liquid state at the operating temperature of the semiconductor die during the testing. Then, the first semiconductor die is positioned in a test apparatus such that the first surface of the first semiconductor die is coupled to the connector in the test apparatus and the thermal interface is coupled to the heat-removal device in the test apparatus.

In some embodiments, the method involves applying the thermal interface material to the heat-removal device prior to the positioning.

In some embodiments, the method additionally involves applying the thermal interface to the second surface of the second semiconductor die. Then, the second semiconductor die is positioned in the test apparatus such that the first surface of the second semiconductor die is coupled to the connector and the thermal interface is coupled to the heat-removal device, thereby facilitating simultaneous testing of the first semiconductor die and the second semiconductor die.

Another embodiment provides an apparatus that performs electrical testing. This apparatus includes: the connector, a mechanism that is configured to apply the liquid metal to the second surface of the first semiconductor die thereby providing the thermal interface, and the heat-removal device configured to be coupled to the thermal interface.

### BRIEF DESCRIPTION OF THE FIGURES

FIG. 1A is a block diagram illustrating test equipment in accordance with an embodiment of the present invention.

FIG. 1B is a block diagram illustrating test equipment in accordance with an embodiment of the present invention.

FIG. 1C is a block diagram illustrating test equipment in accordance with an embodiment of the present invention.

FIG. 2 is a block diagram illustrating a thermal model of a thermal interface in accordance with an embodiment of the present invention.

FIG. 3 is a block diagram illustrating test equipment in accordance with an embodiment of the present invention.

FIG. 4A is a block diagram illustrating test equipment in accordance with an embodiment of the present invention.

FIG. 4B is a block diagram illustrating test equipment in accordance with an embodiment of the present invention.

FIG. 5 is a flow chart illustrating a process for performing electrical testing in accordance with an embodiment of the present invention.

Note that like reference numerals refer to corresponding parts throughout the drawings.

### DETAILED DESCRIPTION

The following description is presented to enable any person skilled in the art to make and use the invention, and is provided in the context of a particular application and its requirements. Various modifications to the disclosed embodiments will be readily apparent to those skilled in the art, and the general principles defined herein may be applied to other embodiments and applications without departing from the spirit and scope of the present invention. Thus, the present invention is not intended to be limited to the embodiments shown, but is to be accorded the widest scope consistent with the principles and features disclosed herein.

Embodiments of an apparatus and a technique for performing electrical testing (such as functional testing, frequency testing, burn-in testing, and/or accelerated life testing) of a semiconductor die or chip are described. In particular, the apparatus, which may include automated test equipment (ATE) and/or semiconductor-die burn-in equipment, has a thermal interface between a semiconductor die under test and a heat-removal device in the apparatus. Note that the heat-removal device may include: a heat sink, a Peltier device, a liquid-cooled cold plate, and/or a thermal reservoir. Furthermore, the thermal interface includes a metal in a liquid state (or more generally, a metal alloy) as a thermal interface material. This metal or metal alloy (henceforth referred to as a liquid metal) may have a low melting point (such as below room temperature or 25 C). More generally, the liquid metal has a melting point which is below an operating temperature during the electrical testing.

In some embodiments, the apparatus is configured to test two or more semiconductor dies at the same time. Note that the liquid metal facilitates a low thermal impedance between the semiconductor dies and the heat-removal device. In an exemplary embodiment, the liquid metal has a bulk thermal conductivity between 7 and 100 W/mK. Furthermore, the thermal impedance may be low even when the semiconductor dies have different thicknesses or if the surfaces of the two semiconductor dies that are in contact with the liquid metal are in different planes.

In some embodiments, the liquid metal is configured to wet the surface of the semiconductor die and is configured to be cleaned off of the surface of the semiconductor die. Furthermore, the heat-removal device may be coated with a layer that facilitates wetting with the liquid metal, the thermal interface, and/or the thermal interface material.

In some embodiments, the liquid metal includes a metal and/or a metal alloy. In an exemplary embodiment, the liquid metal includes gallium-indium-tin. Note that the liquid metal may also include elements other than metals, such as diamond or graphite.

In the discussion that follows, a semiconductor die is understood to include: a bare die, a packaged die, multiple die, and/or two or more die in a single package (which is sometimes referred to as a multichip module).

By using a liquid metal as the thermal interface material, there may be an improved thermal coupling between the heat-removal device and the semiconductor die. This improved thermal coupling facilitates testing of the semiconductor die at elevated temperatures and/or high power. Furthermore, the liquid metal facilitates improved thermal coupling at ambient or at low pressures (i.e., pressures below atmospheric pressure), thereby reducing a risk of damaging the semiconductor die during testing. And the liquid metal may not form a permanent bond with the semiconductor die, thus ensuring that the semiconductor die is easily cleaned after the testing is completed. Thus, by using a liquid metal the testing may be performed more rapidly, more accurately, and/or more precisely (since an uncertainty in the temperature of the semiconductor die may be reduced during testing), and the test equipment may be less complicated and/or less expensive.

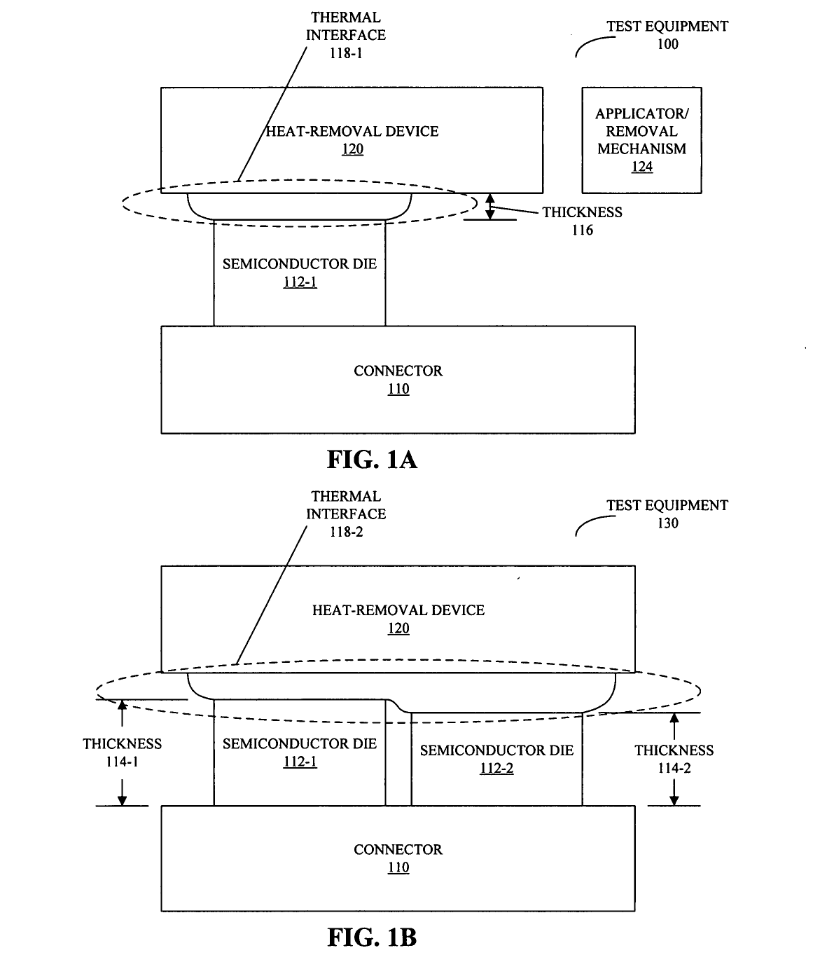

We now describe embodiments of an apparatus and a technique for performing electrical testing. FIG. 1A presents a block diagram illustrating test equipment 100 in accordance with an embodiment of the present invention. In this test equipment, a semiconductor die 112-1 under test is positioned between a connector 110 and a heat-removal device 120. Note that connector 110 facilitates electrical coupling to the semiconductor die 112-1. For example, power, ground, and test signals may be provided to the semiconductor die 112-1 via the connector 110.

During operation, heat is generated by electrical circuits and/or components on the semiconductor die 112-1. To improve the thermal coupling between heat-removal device 120 and the semiconductor die 112-1 (and thus, to improve the transport of heat from the semiconductor die 112-1 to the heat-removal device 120) a thermal interface 118-1 having a thickness 116 may be included between a surface of the semiconductor die 112-1 and a surface of the heat-removal device 120.

In some embodiments, a thermal interface material in the thermal interface 118-1 is applied to either or both the heat-removal device 120 and/or the semiconductor die 112-1 prior to testing, for example, using applicator/removal mechanism 124. This applicator/removal mechanism may include a dropper or a pipette, and may distribute the thermal interface material in the thermal interface 118-1 using mechanic vibration and/or ultrasound. In addition, the applicator/removal mechanism 124 may remove or eliminate excess thermal interface material in and/or proximate to the thermal interface 118-1.

A wide variety of thermal interface materials may be used to provide thermal interfaces, such as thermal interface 118-1. Existing thermal interface materials include: conventional heat-sink grease (such as silicone-based grease), thermally conductive pads, phase-change materials (such as wax-based materials), heat-transfer fluids (such as ethylene glycol or propylene glycol), water, or thermally conductive solders (such as commercially pure indium). However, these thermal interface materials have melting points above room temperature. As discussed below, low-melting point metal alloys (such as a liquid metal that has a melting-point below room temperature or 25 C) have superior physical properties that facilitate improved testing of semiconductor dies.

In particular, low-melting point metal alloys have high bulk thermal conductivities, which may result in a low thermal resistance between the semiconductor die 112-1 and the heat-removal device 120. In turn, a low thermal resistance may reduce the sensitivity during the testing to changes in the thickness 116 of the thermal interface (which is also referred to as a bond-line thickness). In addition, a low thermal resistance may allow the temperature of the semiconductor die 112-1 during testing to be estimated with reduced uncertainty.

Furthermore, these metal alloys are liquids (i.e., a material without shear strength) at room temperature and/or an operating temperature (such as 80, 100, or 125 C) during testing. These physical properties enable these metal allots to conform to the surfaces of the semiconductor dies under test. Consequently, thermal boundary resistances associated with low-melting point metal alloys may be small. As illustrated in FIGS. 1B and 1C (which presents block diagrams of test equipment 130 and 150, respectively, in accordance with embodiments of the present invention), the ability to conform to surfaces may facilitate testing of multiple semiconductor dies 112 at the same time, even though these semiconductor dies have different thicknesses 114 and/or have surfaces that are not coplanar. For example, surfaces of semiconductor dies 112 thermally coupled to thermal interface 118-3 may not be coplanar due to angle 126. Note that these characteristics of the thermal interface material may facilitate testing when the space between the connector 110 and the heat-removal device 120 is limited or restricted.

Referring back to FIG. 1A, in addition the thickness 116 of thermal interface 118-1 may be thin (for example, less than 150 μm) and the thermal interface 118-1 may form at atmospheric or low pressures. This property may simplify the complexity of the test equipment 100, and may reduce or prevent semiconductor dies 112 from being damaged during testing.

Note that a superior thermal interface facilitates improved testing of semiconductor dies 112. For example, a semiconductor die (such as the semiconductor die 112-1) may be tested at its maximum specified power and/or at elevated temperatures. Furthermore, since the metal alloys are already liquid at the operating temperatures during testing, the thermal interface material will not be near a critical thermal breakdown temperature. Also note that testing at higher power and/or temperature may accelerate degradation phenomena, thereby reducing the required test cycle time.

In some embodiments, the liquid metal is configured such that a permanent chemical bond does not occur with the semiconductor dies 112 under test. This property facilitates easier cleaning of the semiconductor dies (without leaving a residue) after the testing is completed and prior to additional processing. (Note that applicator/removal mechanism 124 may clean the semiconductor dies 112.) In addition, the absence of a permanent chemical bond also makes it less likely that the semiconductor dies 112 are damaged during such a cleaning process. In an exemplary embodiment, the thermal interface material is removed using a solder sucker (i.e., by using a vacuum) and/or using a mechanical wipe. In some embodiments, the cleaning process may involve the use of acetone and/or isopropyl alcohol.

Note that in some embodiments test equipment 100, 130, and/or 150 include fewer or additional components, two or more components are combined into a single component, and/or a position of one or more components may be changed.

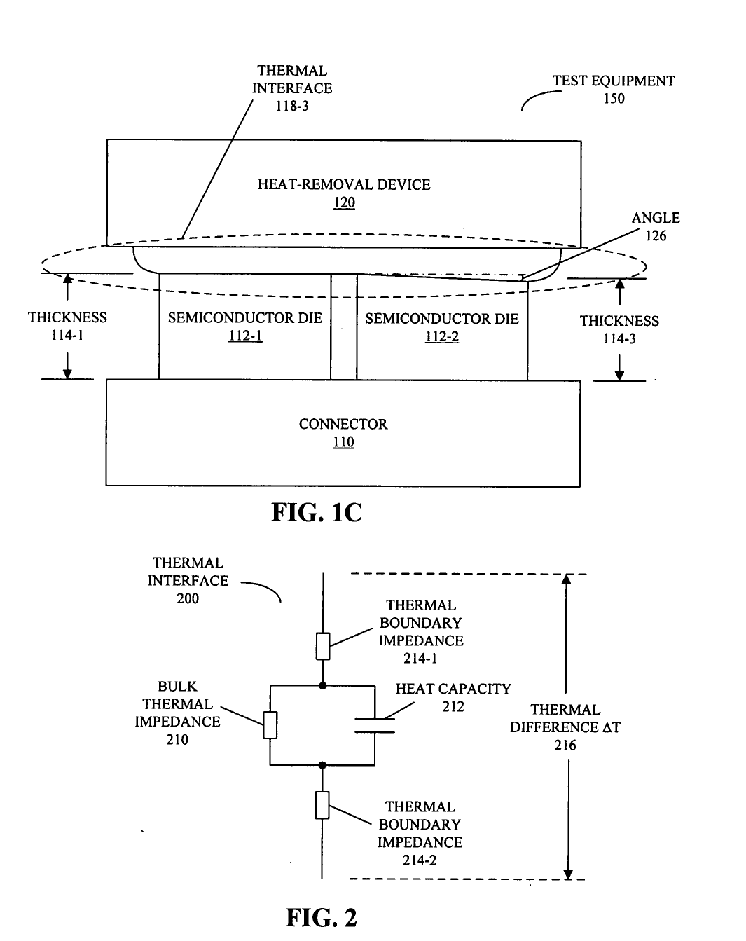

Properties of thermal interfaces (such as thermal interface 118-1 in FIG. 1A) are illustrated by FIG. 2, which presents a thermal model of a thermal interface 200 in accordance with an embodiment of the present invention. In this discrete thermal model, the thermal interface material has a bulk thermal impedance 210 (which is inversely proportional to the bulk thermal conductivity), a heat capacity 212, and thermal boundary impedances 214. As discussed above, liquid metals have low thermal boundary impedances 214 and a low bulk thermal impedance 210 due to a high bulk thermal conductivity. For example, the thermal interface material may have a bulk thermal conductivity between 7 and 100 W/mK. Consequently, a thermal difference or gradient ΔT 216 between the semiconductor dies 112 (FIGS. 1A-1C) and the heat-removal device 120 (FIGS. 1A-1C) may be significantly reduced or eliminated relative to the thermal gradient associated with other thermal interface materials.

In an exemplary embodiment, the thermal interface material in the thermal interfaces 118 (FIGS. 1A-1C) includes: bismuth, lead, zinc, sliver, gold, tin, chromium, nickel, aluminum, palladium, platinum, tantalum, gallium, indium, and/or titanium. For example, the thermal interface material may include metallic particles of one or more of the preceding materials. In some embodiments, the thermal interface material is an alloy that includes 1,2, 3, or more metal elements. For example, the liquid metal may be an alloy that includes gallium, indium, and tin. In some embodiments, the thermal interface material is a eutectic material.

Furthermore, in some embodiments the liquid metal may be doped with other materials, such as diamond and/or graphite. These materials may increase or enhance interfacial adhesion between the liquid metal in the thermal interface 118 (FIGS. 1A-1C) and the semiconductor dies 112 (FIGS. 1A-1C). However, such non-metal materials may not obstruct cleaning of the semiconductor dies 112 (FIGS. 1A-1C) after the testing is completed. In general, the liquid metal may include a variety of organic and/or inorganic compounds.

In an exemplary embodiment, the thermal interface 1 18 (FIGS. 1A- 1C) has a thickness 116 (FIG. 1A) between 30-150 μm at atmospheric pressure or at a contact pressure of 5 psi.

In an illustrative embodiment, the thermal interface material is a gallium-indium-tin alloy and has a bulk thermal conductivity of 31 W/mK. If a semiconductor die has a surface area of 1.43 e-4 m² and the thermal interface has a thickness 116 (FIG. 1A) of 7.5 e-5 m, the bulk thermal impedance 210 of the thermal interface 118 (FIGS. 1A-1C) is less than 0.02 K/W.

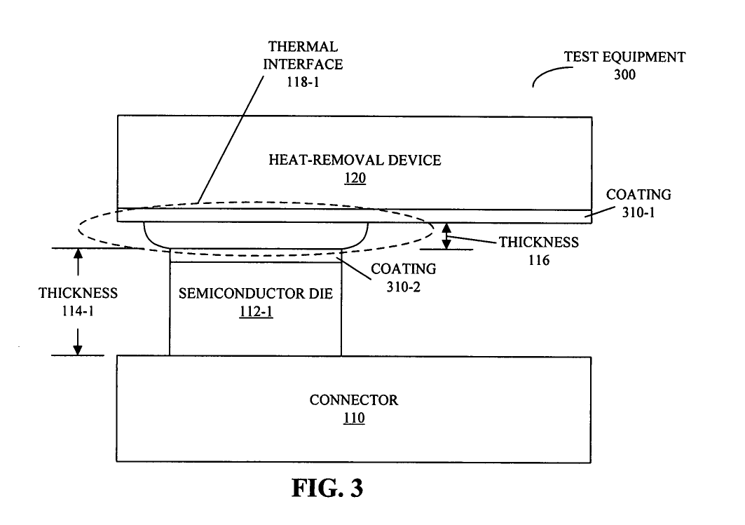

We now describe alternate embodiments of an apparatus for performing electrical testing. FIG. 3 presents a block diagram illustrating test equipment 300 in accordance with an embodiment of the present invention. In this equipment, either or both of the heat-removal device 120 and/or the semiconductor die 112-1 may include coatings 310. These coatings 310 may facilitate wetting with the thermal interface material (such as the liquid metal) in the thermal interface 118-1. In an exemplary embodiment, the coatings 310 include a metal (or more generally, a metal alloy), such as gold, platinum, tantalum, titanium, tin, chromium, nickel, zinc, silver, and/or aluminum. Furthermore, in some embodiments the coatings 310 may include an adhesion promoter, such as an RCA-1 surface preparation, a silated promoter, and/or an adhesive (for example, epoxy).

Coatings 310 may be applied using techniques such as plating, evaporation, and/or sputtering. In addition, one or both of the coatings 310 may intentionally roughened (for example, using electromechanical polishing) to promote adhesion.

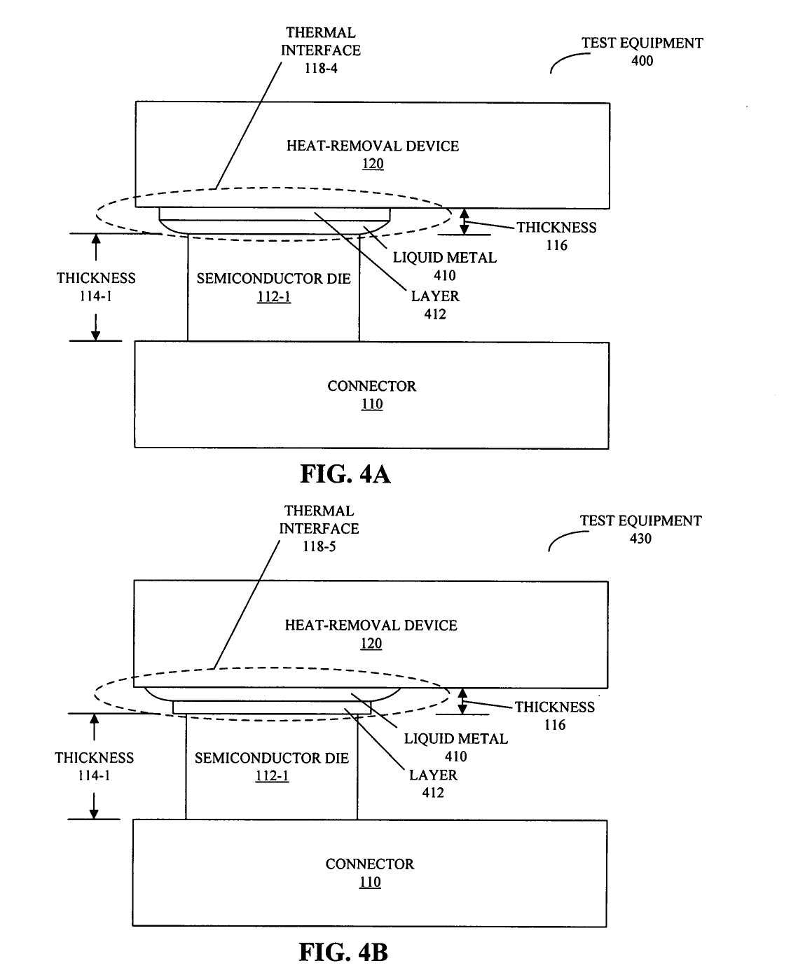

In some embodiments, the thermal interface 118 includes a layer having a bulk thermal conductivity that is greater than the bulk thermal conductivity of the liquid metal. This is illustrated in FIGS. 4A and 4B, which presents block diagrams of test equipment 400 and 430, respectively, in accordance with embodiments of the present invention. Thus, thermal interfaces 118-4 and 118-5 include a liquid metal 410 and a layer 412.

Note that in some embodiments test equipment 300 (FIG. 3), 400, and/or 430 include fewer or additional components, two or more components are combined into a single component, and/or a position of one or more components may be changed. For example, there may be multiple coatings 310 (FIG. 3) and/or multiple layers 412 (FIGS. 4A and 4B).

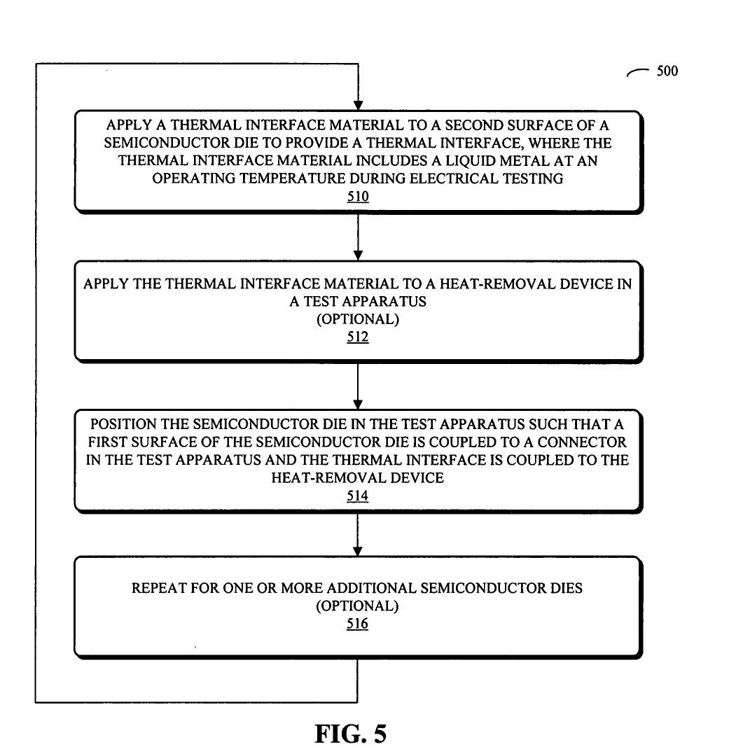

We now discuss methods for performing electrical testing. FIG. 5 presents a flow chart illustrating a process 500 for performing electrical testing in accordance with an embodiment of the present invention. During this method, a thermal interface material is applied to a second surface of a semiconductor die to provide a thermal interface (510). Note that the thermal interface material includes a liquid metal and/or a liquid-metal alloy at an operating temperature during electrical testing. Then, the thermal interface material is optionally applied to a heat-removal device in a test apparatus (512).

Next, the semiconductor die is positioned in the test apparatus such that a first surface of the semiconductor die is coupled to a connector in the test apparatus and the thermal interface is coupled to the heat-removal device (514). In some embodiments, the applying 510 and/or 512, and the positioning 514 operations are optionally repeated for one or more additional semiconductors (516). Note that in some embodiments there may be additional or fewer operations, the order of the operations may be changed, and two or more operations may be combined into a single operation.

While the use of liquid metals as a thermal interface material in thermal interfaces has been described in the context of electrical testing of semiconductor dies, the apparatus and techniques described above may be applied in thermal interfaces during the testing of other devices and/or components.

The foregoing descriptions of embodiments of the present invention have been presented for purposes of illustration and description only. They are not intended to be exhaustive or to limit the present invention to the forms disclosed. Accordingly, many modifications and variations will be apparent to practitioners skilled in the art. Additionally, the above disclosure is not intended to limit the present invention. The scope of the present invention is defined by the appended claims.

What is claimed is:

1. An apparatus that performs electrical testing, comprising:
a first semiconductor die to be tested;
a connector configured to be coupled to a first surface of the first semiconductor die;
a thermal interface coupled to a second surface of the first semiconductor die, wherein the thermal interface includes a metal which is in a liquid state at an operating temperature of the first semiconductor die during the electrical testing; and
a heat-removal device coupled to the thermal interface.

2. The apparatus of claim 1, further comprising a second semiconductor die that is to be simultaneously tested with the first semiconductor die, wherein the second semiconductor die is adjacent to the first semiconductor die, and wherein a first surface of the second semiconductor die is coupled to the connector and a second surface of the second semiconductor die is coupled to the thermal interface.

3. The apparatus of claim 2, wherein the second surface of the second semiconductor die is in a different plane than the second surface of the first semiconductor die.

4. The apparatus of claim 1, wherein the heat-removal device is coated with a layer that facilitates wetting with the thermal interface.

5. The apparatus of claim 4, wherein the layer includes a metal.

6. The apparatus of claim 5, wherein the metal includes gold, tin, platinum, tantalum, titanium, chromium, nickel, zinc, silver, or aluminum.

7. The apparatus of claim 1, wherein the liquid metal is configured to wet to the second surface of the first semiconductor die.

8. The apparatus of claim 1, wherein the liquid metal includes a metal alloy.

9. The apparatus of claim 8, wherein the metal alloy includes gallium-indium-tin.

10. The apparatus of claim 1, wherein the liquid metal includes bismuth, lead, zinc, sliver, gold, tin, chromium, nickel, aluminum, palladium, platinum, tantalum, gallium, indium, or titanium.

11. The apparatus of claim 1, wherein the liquid metal includes elements other than metals.

12. The apparatus of claim 11, wherein the other elements include diamond or graphite.

13. The apparatus of claim 1, wherein the liquid metal has a bulk thermal conductivity between 7 and 100 W/mK.

14. The apparatus of claim 1, wherein a thickness of the liquid metal between the second surface and the heat-removal device is between 30-150 μm.

15. The apparatus of claim 1, wherein the thermal interface includes a layer between the liquid metal and the heat-removal device, and wherein the layer has a bulk thermal conductivity which is greater than a bulk thermal conductivity of the liquid metal.

16. The apparatus of claim 1, wherein the thermal interface includes a layer between the liquid metal and the first semiconductor die, and wherein the layer has a bulk thermal conductivity which is greater than a bulk thermal conductivity of the liquid metal.

17. The apparatus of claim 1, wherein the liquid metal has a melting temperature below room temperature.

18. The apparatus of claim 1, wherein the thermal interface is removable and the liquid metal is configured to be cleaned off of the second surface of the first semiconductor die.

19. The apparatus of claim 1, wherein electrical testing includes functional testing or burn-in testing.

20. A method for performing electrical testing, comprising:
applying a thermal interface material to a second surface of a first semiconductor die to provide a thermal interface, wherein the thermal interface material includes a metal in a liquid state at an operating temperature of the first semiconductor die during the electrical testing; and
positioning the first semiconductor die in a test apparatus such that a first surface of the first semiconductor die is coupled to a connector in the test apparatus and the thermal interface is coupled to a heat-removal device in the test apparatus.

21. The method of claim 20, further comprising applying the thermal interface material to the heat-removal device prior to the positioning.

22. The method of claim 20, further comprising applying the thermal interface material to a second surface of a second semiconductor die; and
positioning the second semiconductor die in the test apparatus such that a first surface of the second semiconductor die is coupled to the connector and the thermal interface material is coupled to the heat-removal device, thereby facilitating simultaneous testing of the first semiconductor die and the second semiconductor die, wherein the second semiconductor die is adjacent to the first semiconductor die.

23. The method of claim 22, wherein the second surface of the second semiconductor die is in a different plane than the second surface of the first semiconductor die.

24. An apparatus that performs electrical testing, comprising:
a connector configured to be coupled to a first surface of a first semiconductor die that is tested;
a mechanism that is configured to apply a metal in a liquid state to a second surface of the first semiconductor die thereby providing a thermal interface, wherein the metal is in the liquid state at an operating temperature of the first semiconductor die during the electrical testing; and
a heat-removal device configured to couple to the thermal interface.
